(19) United States
(12) Patent Application Publication
(10) Pub. No.: US 2022/0328988 A1
(43) Pub. Date: Oct. 13, 2022

(54) CURRENT CONVERTER FOR A VEHICLE

(71) Applicants: INTERPLEX NAS ELECTRONICS GMBH, Heilbronn (DE); ZF FRIEDRICHSHAFEN AG, Friedrichshafen (DE)

(72) Inventors: Pengshuai WANG, Friedrichshafen (DE); Thomas BOSCH, Ravensburg (DE); Michael KOHR, Bodnegg (DE); Matthias BERGFELD, Heilbronn (DE)

(21) Appl. No.: 17/642,354

(22) PCT Filed: Sep. 10, 2020
(86) PCT No.: PCT/EP2020/075296

§ 371 Date: Mar. 11, 2022

(30) Foreign Application Priority Data
Sep. 11, 2019 (DE) 10 2019 213 855.1

(51) Int. Cl. H01R 12/52; H01R 13/66; B60L 53/16

(52) U.S. Cl. CPC H01R 12/523; H01R 13/6625; B60L 53/16; H01R 2201/26

(57) ABSTRACT

A power converter, for a vehicle that is at least partially electrically powered, has a first printed circuit board with DC link capacitors, a circuit breaker group for each alternating current phase, and terminals for alternating current busbars and direct current busbars. A second printed circuit board has a control apparatus for actuating the circuit breaker groups. Also, it has a respective signal pin carrier for the respective circuit breaker group. The signal pin carrier connects the first and the second printed circuit board. Thus, signals between the first and the second printed circuit board can be transmitted via the respective signal pin carrier. The signal pin carrier has six signal pins that are arranged on a plastic carrier.

### CROSS-REFERENCE TO RELATED APPLICATIONS

This application is a 371 U.S. National Phase of International Application No. PCT/EP2020/075296, filed Sep. 10, 2020, which claims priority to German Patent Application No. 10 2019 213 855., filed Sep. 11, 2019. The entire disclosures of the above applications are incorporated herein by reference.

### FIELD

The disclosure relates to a power converter for a vehicle that is at least partially electrically driven.

### BACKGROUND

A converter device is known from EP 2 099 199 B1 that has circuit breakers on a first board and between direct current (DC) link capacitors on a second board.

By contrast, the power converter according to the disclosure for a vehicle that is at least partially electrically driven has the advantage that the use of a respective signal pin carrier for a respective circuit breaker group means that a path of the shortest possible length can be provided for signal transmission from one printed circuit board to the other printed circuit board, and vice versa. This reduces the influence of electromagnetic interference and enables fast switching times and a high switching frequency. In addition, the space requirement is low by virtue of the solution according to the disclosure. The manufacturing tolerances and the manufacturing steps are also robust and efficient.

### SUMMARY

Therefore, a power converter for a vehicle is proposed that is at least partially electrically driven and has a first printed circuit board with DC link capacitors, a circuit breaker group for each alternating current (AC) phase, and terminals for AC busbars and DC busbars. A second printed circuit board has a control apparatus for actuating the circuit breaker groups. It also includes a respective signal pin carrier for a respective circuit breaker group. The respective signal pin carrier connects the first and the second printed circuit board such that signals between the first and the second printed circuit board can be transmitted via the respective connected signal pin carrier. The signal pin carrier has six signal pins that are arranged on a plastic carrier.

A power converter for a vehicle is to be understood as a device that converts direct current into alternating current, preferably into three-phase alternating current, in order to drive one or more electric motors. The power converter can also be set up to convert alternating current into direct current.

The vehicle is usually a passenger car that is at least partially electrically powered. In particular, the vehicle can be understood to be a hybrid vehicle that is driven both by combustion technology and by an electric motor. This is to be preferably understood as a so-called mild hybrid where the internal combustion engine runs continuously and the electric motor is switched on in addition.

In the case of the first printed circuit board, it usually has a structure including a copper foil or copper layer, with an insulating layer underneath, for example, ceramic or polymer, and underneath that an aluminum layer. The conductor tracks and other structures are made from the copper layer or foil. For example, heat is dissipated via the insulation layer. The aluminum layer is used, for example, to short out eddy currents and also helps to distribute heat across the printed circuit board. A so-called thermal interface material (TIM), having a gap filler with glass beads, can then be located beneath the aluminum layer. A cooling device is usually connected to dissipate the heat, for example, by water. The DC link capacitors are arranged on this first printed circuit board and absorb the direct current from the DC busbars. The DC current is then to be converted into an alternating current. Furthermore, respective circuit breaker groups are provided for the respective AC phases on the first printed circuit board. In such a circuit breaker group, there is a so-called high-side switch and a so-called low-side switch. A high-side switch can include, for example, three or four individual transistors, preferably MOSFETs. These are connected in parallel and together form the high-side switch. The same applies to the low side. Upon actuation of these circuit breakers, the direct current is converted into an alternating current through chopping. The transistors are usually actuated by pulse-width modulation. The AC busbars are arranged, for example, between the two switches on the high-side switch and the low-side switch. The AC current can be passed on from there to the electric motor. Preferably, three circuit breaker groups are provided for the three AC phases. Furthermore, connections for the DC busbars, i.e., the positive and negative poles, are provided in order to make the direct current from the vehicle battery or from a rectifier, for example, available for conversion into alternating current.

The second printed circuit board has the control apparatus for actuating the circuit breaker groups. Accordingly, the pulse-width modulation is preferably produced here. This is done particularly as a function of input signals and specified control parameters. The input signals can be current measurements at the outputs of the circuit breakers, for example. So-called harmonics, which occur when converting direct current into alternating current, can also influence the actuation of the circuit breaker groups. For example, a microcontroller can be provided here for the actuation, but there can also be an additional vehicle plug, such as a connection to the CAN bus, for example, on the second printed circuit board. The circuit breaker groups are actuated via the respective signal pin carrier. This means that there is a signal pin carrier for each circuit breaker group. This signal pin carrier has a plastic carrier where the six signal pins are arranged. Not only are the circuit breaker groups actuated via these signal pins, but the signals are also routed from the circuit breaker groups to the microcontroller, for example. This ensures all communication between the first and the second printed circuit board via this signal pin carrier. The signal pin carriers are metal structures that enable the signals to be transmitted with as little loss as possible. The plastic carrier is not only intended to accommodate these signal pin carriers but is also designed for installation between the first and second printed circuit boards.

Advantageous refinements of the power converter for a vehicle are defined in the dependent claims.

The six signal pins are connected to the plastic carrier through injection of plastic around them. Such injection, for example in the form of overmolding, is a very cheap and reliable method for producing the plastic carrier.

In addition, the six signal pins are pressed through the second printed circuit board. The connection to the second printed circuit board can thus be produced, for example, by what is known as a press-fit. Alternatively, it is also possible for materially bonded connections to be implemented, for example by soldering.

Furthermore, the signal pins each have two portions for compensation. The first portion is provided, for example, for the press-fit specified above. This portion must be designed so that it is possible to press it through the second printed circuit board but then also to be secured. The second compensating element is intended for connecting to the first printed circuit board and imparts a robustness to the manufacturing process.

Furthermore, the six signal pins have a spring region as one portion. This spring region is intended particularly for making contact with the first printed circuit board and enables the signal pins to be pressed onto this first printed circuit board.

In addition, each of the signal pins presses onto a surface of the first printed circuit board and is soldered there. Therefore, if the signal pins are first pressed into the second printed circuit board and then this structure is pressed onto the first printed circuit board, no pressing-through occurs here, but rather only a pressing-on of the first printed circuit board, followed by fixation by soldering. The spring elements are therefore especially suitable here as a compensating portion.

In addition, the plastic carrier has at least one positioning pin to position the signal pins on the first printed circuit board. With such a positioning pin, the plastic carrier can be placed optimally in the intended position. Thus, the signal pins then press onto the correct location on the surface of the first printed circuit board.

Furthermore, the plastic carrier has at least one stop. Thus, the signal pins are compressed with the second printed circuit board while being pressed on until the stop strikes the surface of the first printed circuit board. With this stop, or shoulder, a predetermined pressing force is defined on the surface of the first printed circuit board by the signal pins.

Furthermore, the plastic carrier has a mirror-symmetrical design. This imparts a robustness to the manufacturing process, since the plastic carrier cannot be pressed incorrectly into the second printed circuit board, for example. After all, it is symmetrical. This means that no further measures are required for production in order to prevent incorrect installation.

In addition, the stop is designed so that the stop prevents the plastic carrier from tilting. Thus, the stop or shoulder is designed, for example, to be point-symmetrical to the center. Thus, this imparts a high level of stability to the plastic carrier when it rests on the first printed circuit board and prevents the plastic carrier from tilting.

In addition, two signal pin carriers are respectively provided for the source, drain, and gate of the circuit breakers. The gates are actuated and current measurements are carried out at the source and drain.

In addition, the signal pins have the compensating portion, which is compressible, for pressing through the second printed circuit board.

In addition, this compensating portion is open. Thus, there is no material in the middle, so this open region allows compression to occur during pressing-through.

Furthermore, one end of the signal pin, that is pressed through the second printed circuit board, has a tip. Thus, that end of the signal pin that is pressed through the second circuit board is shaped like the tip of a spear or arrow. The open region can be like a longitudinal section.

Further measures and features according to the disclosure can be as follows in preferred embodiments.
a) The number of signal pins can vary depending on the application. Thus, two or more signal pins can be provided, with at least 2 signal pins preferably being provided in each case for actuating the drain, source, and gate.
b) A compensating region is instantiated as an elastically resilient region (spring region) that is preferably embodied as a meandering or S-shaped spring region.
c) The contact carrier is preferably mirror-symmetrical and, more preferably, has a V-shaped portion in a central region. The V-shaped tip advantageously projects in the direction of the first printed circuit board and is advantageously supported on the first printed circuit board. This has advantages for stability and assembly.
d) The contact carrier or plastic carrier is designed so that the signal pins are arranged in a row relative to one another. A first group of signal pins and a second group of signal pins are provided in the row arrangement. A V-shaped portion of the plastic carrier is embodied between the first and second groups. The V-shaped tip protrudes in the direction of the first printed circuit board.
e) The plastic carrier has a cuboid web for carrying the signal pins, as well as cuboid blocks in the vicinity of the overmolding of the signal pins, each of which extends from the web in the direction of the second printed circuit board.
f) The signal pin printed circuit board press-in zones have a compressible region in the shape of the eye of a needle, particularly, one that is materially bonded to the front side and includes two signal pin arms each.
g) The effective cross section of the signal pins, in the direction of connection, decreases or tapers in a region between the overmolding portion.

Further areas of applicability will become apparent from the description provided herein. The description and specific examples in this summary are intended for purposes of illustration only and are not intended to limit the scope of the present disclosure.

### DRAWINGS

Exemplary embodiments of the disclosure are illustrated in the drawing and elucidated in further detail in the following description.

FIG. 1 is an elevation view of a first side of the signal pin carrier;

FIG. 2 is a plan view of the signal pin carrier from below;

FIG. 3 is a side perspective view of the signal pin carrier in the installed state;

FIG. 4 is a side elevational view of the built-in signal pin carrier in the installed position; and

FIG. 5 is a cross section view of the signal pin carrier in the installed state.

### DETAILED DESCRIPTION

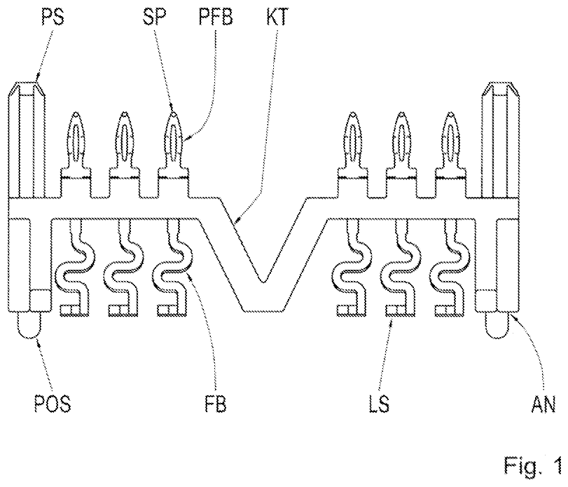

FIG. 1 shows the signal pin carrier in a side elevation view. On both sides there are structures for a positioning pin POS for contacting the first printed circuit board and a positioning pin for positioning on the second printed circuit board. Each of these two positioning pins has a stop or shoulder AN on its side for the first printed circuit board. This defines the force with which the signal pins SP are pressed onto the first printed circuit board but is also designed in such a way that tilting of the signal pin carrier on the first printed circuit board is prevented. The plastic carrier KT has a mirror-symmetrical design. The signal pins are also arranged in mirror symmetry, apart from the compensating structure of the spring structure for the first printed circuit board. This spring region is denoted with FB. The signal pins have in their upper region a compensating region, a so-called press-fit region PFB, that is compressed when it is pressed through the holes in the second printed circuit board. If they are pressed through, the compression decreases and fixation is achieved. As can be seen here, the signal pins, in this upper region have the appearance of arrowheads or spearheads to press through the second printed circuit board. In the lower region, for contacting the first printed circuit board, the signal pins SP have the spring region FB and the contact structure. This results in soldering LS to the second printed circuit board. The positioning pins POS and PS are also arranged mirror-symmetrically in the present case.

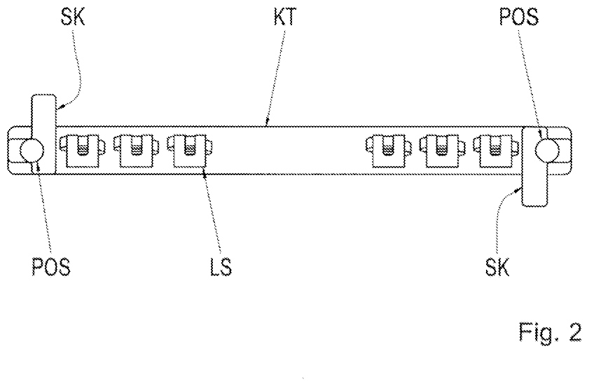

FIG. 2 shows a plan view of the signal pin carrier from below. The two positioning pins POS are again shown symmetrically to the center of the signal pin carriers, as is the plastic carrier KT. The shoulders SK, that prevent tilting, are point-symmetrical to the center of the plastic carrier. Thus, they impart a high level of stability to the signal pin carrier on the first printed circuit board and prevent tilting. The soldering point LS is also shown for the signal pins.

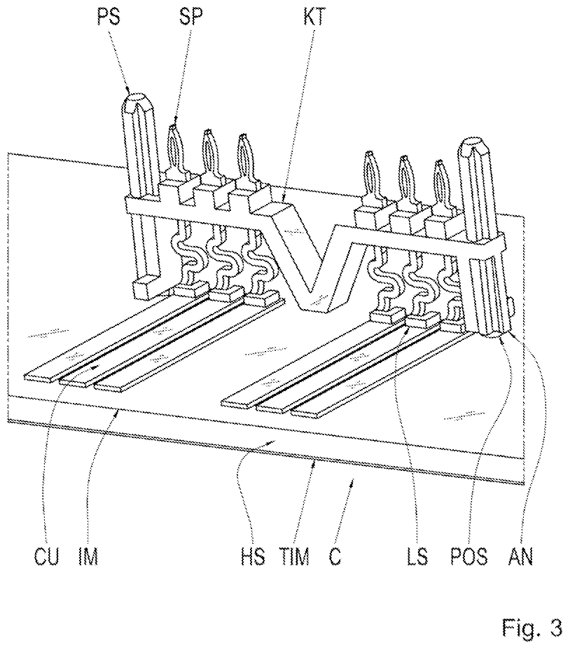

FIG. 3 shows the signal pin carrier in the installed state. The plastic carrier is shown symmetrically with the two positioning pins POS and PS. The signal pin carriers SP lie on the first printed circuit board. They are soldered there and connected to a copper conductor track. This is denoted with CU. The soldering points of the signal pins are also denoted with LS. The shoulder AN is also shown, as well as the positioning pin POS. The insulating layer IM of the first printed circuit board is located beneath the copper tracks. The heat is transferred via this insulating layer to the aluminum layer HS. The aluminum layer HS distributes the heat or warmth over the printed circuit board. The thermal interface material TIM connects the printed circuit board to the cooler C, which is located beneath the aluminum layer HS. The cooler C has a fluid cooling system, which then transports the heat away.

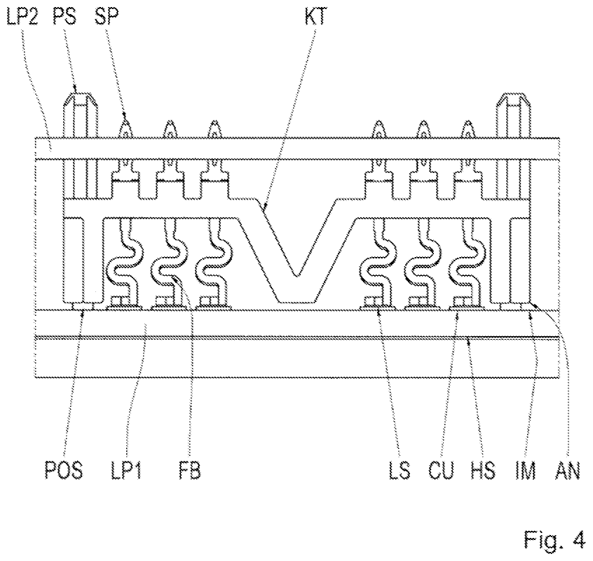

FIG. 4 shows the signal pin carrier in the installed state in cross section. Positioning pins PS and POS are again shown on the sides, as well as the shoulder AN. The six signal pins SP are also shown in the installed state. This also shows how the positioning pin PS is passed through the second printed circuit board LP2. The signal pins, with their compressible structure, are inserted in the second printed circuit board LP and protrude slightly over the same. The positioning pins POS, which enable the six signal pins to be positioned on the first printed circuit board, are introduced in the lower region of the first printed circuit board LP1. This enables soldering at the soldering points LS on the copper layer CU of the first printed circuit board LP1. Below this copper layer CU is the insulation layer IM, and below that is the aluminum layer HS, as described above.

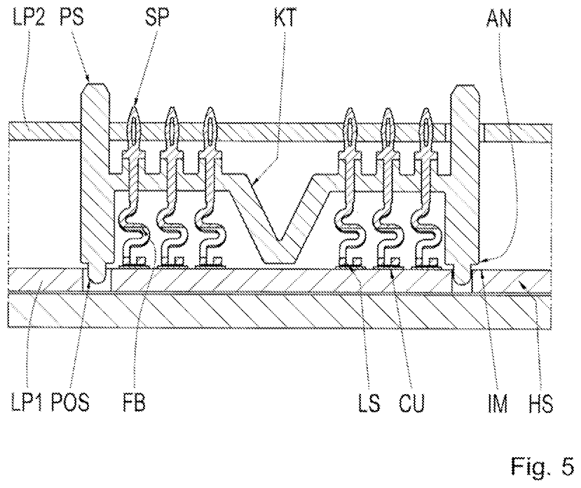

FIG. 5 again shows the signal pin carrier in the installed state in cross section. The printed circuit board LP1 is connected to the plastic carrier KT via the positioning pins POS. The signal pins SP are connected on the first printed circuit board LP1 and thereby on the copper layer CU via the solder points LS. As already shown, the signal pin carriers have the compensating region FB as a spring element in the lower region. The shoulder or the stop AN is also shown and defines the pressing force of the signal pins onto the first printed circuit board LP1. The signal pin carriers are shown here again as they are pressed through the second printed circuit board LP2 with their tips. The positioning pins PS are also passed through the second printed circuit board.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1.-15. (canceled)

16. A power converter for a vehicle that is at least partially electrically powered, comprising:
a first printed circuit board having direct current (DC) link capacitors, a circuit breaker group for each alternating current (AC) phase, and terminals for AC busbars and DC busbars;
a second printed circuit board having a control apparatus for actuating the circuit breaker groups; and
a respective signal pin carrier for a respective circuit breaker group, the signal pin carrier connects the first and the second printed circuit board such that signals between the first and the second printed circuit board can be transmitted via the respective signal pin carrier, and the signal pin carrier has a plurality of six, signal pins that are arranged on a plastic carrier.

17. The power converter as set forth in claim 16, wherein the signal pins are connected to the plastic carrier through overmolding with plastic.

18. The power converter as set forth in claim 16 wherein the signal pins are pressed through the second printed circuit board and protrude with their tip on one side of the second printed circuit board.

19. The power converter as set forth in claim 16, wherein the signal pins each have two compensating regions for the respective contacting of the first and the second printed circuit board.

20. The power converter as set forth in claim 19, wherein a first compensating region in the signal pins have a spring region that embodies a meandering or S-shaped spring region.

21. The power converter as set forth in claim 16, wherein each of the signal pins presses onto a contact surface on the first printed circuit board and is soldered there.

22. The power converter as set forth in claim 21, wherein the plastic carrier has at least one positioning pin for positioning the signal pins on the first printed circuit board.

23. The power converter as set forth in claim 21, wherein the plastic carrier has at least one stop, so that the signal pins are compressed with the second printed circuit board until the stop strikes the surface of the first printed circuit board.

24. The power converter as set forth in claim 16, wherein the plastic carrier is mirror-symmetrical and has a V-shaped portion in a central region.

25. The power converter as set forth in in claim 24 wherein the plastic carrier is designed so that the signal pins are arranged in a row relative to one another, the V-shaped portion of the plastic carrier is between the groups of signal pins with a first group of signal pins and a second group of signal pins. Also the V-shaped tip protrudes in the direction of the first printed circuit board.

26. The power converter as set forth in claim 16, wherein the plastic carrier has a cuboid web for carrying the signal pins, as well as cuboid blocks in the vicinity of an overmolding of the signal pins, each of which extends from the web in the direction of the second printed circuit board.

27. The power converter as set forth in claim 16, wherein the stop is designed to prevent the plastic carrier from tilting.

28. The power converter as set forth in claim 16, wherein two signal pin carriers are respectively provided for the source, drain, and gate of the circuit breakers, the gates being actuated and current measurements being carried out at the source and drain.

29. The power converter as set forth in claim 18, wherein the signal pins for contacting the second printed circuit board have a compressible region in the shape of the eye of a needle, particularly one that is materially bonded to the front side and includes two signal pin arms each.

30. The power converter as set forth in claim 16, wherein the effective cross section of the signal pins decreases, or the effective cross section tapers off, in a region between an overmolding portion and a soldering portion in the connection direction.
